(19) United States
(12) Patent Application Publication
(10) Pub. No.: US 2010/0209728 A1
(43) Pub. Date: Aug. 19, 2010

(54) MAGNETRON CO-SPUTTERING DEVICE

(75) Inventors: Jean-Pierre Dauchot, Mons (BE); Corinne Nouvellon, Mons (BE)

Correspondence Address: Jerold I. Schneider, 525 Okeechobee Blvd., Suite 1500, West Palm Beach, FL, 33401, US

(73) Assignee: Materia Nova, Mons (BE)

(21) Appl. No.: 12/668,317

(22) PCT Filed: Jul. 11, 2008
(86) PCT No.: PCT/EP2008/059088

§ 371 Date: Apr. 20, 2010

(30) Foreign Application Priority Data
Jul. 12, 2007 (GB) 0713450.5

(51) Int. Cl. C23C 14/35; B32B 15/04

(52) U.S. Cl. 428/544; 204/298.16; 428/469; 428/457

(57) ABSTRACT

The present invention provides a magnetron co-sputtering device (6) comprising a main magnetron cathode (x) and a secondary cathode (Y) adapted to be associated with each other to sputter deposit a material on a substrate (2) arranged at a substrate position, the material comprising a first material derived from the main cathode (X) and a second material derived from the secondary cathode (Y), wherein the secondary cathode (Y) is arranged between the main cathode (X) and the substrate position, at a position selected from: (i) a position within a magnetic field derived from a main cathode (X) magnetic source, and (ii) a position within the footprint (6) of the main cathode (X).

The present invention relates to a magnetron sputtering device for coating a substrate; in particular, it relates to a magnetron co-sputtering device to sputter deposit on a substrate a layer comprising a first material derived from a first cathode and a second material derived from a second cathode.

Conventionally, co-sputtering is carried out using two cathodes side by side, either planar cathodes or rotating cylindrical cathodes. A first material is derived from the first cathode and a second material is derived from the second cathode. The first and second materials mix with each other at a close proximity to the substrate to be coated or on the substrate itself. A system of this type is described in WO92/01081A1.

According to one of its aspects, the present invention provides a magnetron co-sputtering device as defined by claim 1. Dependent claims define preferred and/or alternative aspects of the invention.

According to this aspect, there is provided a magnetron co-sputtering device comprising a main magnetron cathode and a secondary cathode adapted to be associated with each other to sputter deposit a material on a substrate arranged at a substrate position, the material comprising a first material derived from the main cathode and a second material derived from the secondary cathode, wherein the secondary cathode is arranged between the main cathode and the substrate position, at a position selected from:

(i) a position within a magnetic field derived from a main cathode magnetic source, and
(ii) a position within the footprint of the main cathode.

This may provide advantages including one or any combination of:
both cathodes may use a single standard cathode position, which may be configuration and cost effective; this may for example, leave an emplacement free for another cathode or an identical device may be placed next to the first one to increase the rate of deposition;
the secondary cathode may be installed on an existing magnetron sputtering line; this may be useful if an existing line has no free positions available and a mixed layer is desired (adding of a cathode position to a sputtering line is time consuming and expensive);
the secondary cathode may be used in combination with any type of main cathode (e.g. planar or rotating cylindrical cathodes);
the secondary cathode may be relatively easily installed; this system may consequently be flexible in terms of production; it may for example be easily dismounted when not needed; it may be easily retrofitted to existing coaters;
the secondary cathode may contain less material than a conventional cathode; it may be less voluminous; this may be of interest when it is used only occasionally and/or includes an expensive material to be sputtered.
the coating obtained on the substrate may be more uniform than with previous known co-sputtering systems; distribution of both materials in the coating may be more homogeneous. This may be due to the sputtering cones of the first and second materials being advantageously arranged along the same axis and mixing of the materials taking place significantly before deposition on the substrate to be coated.

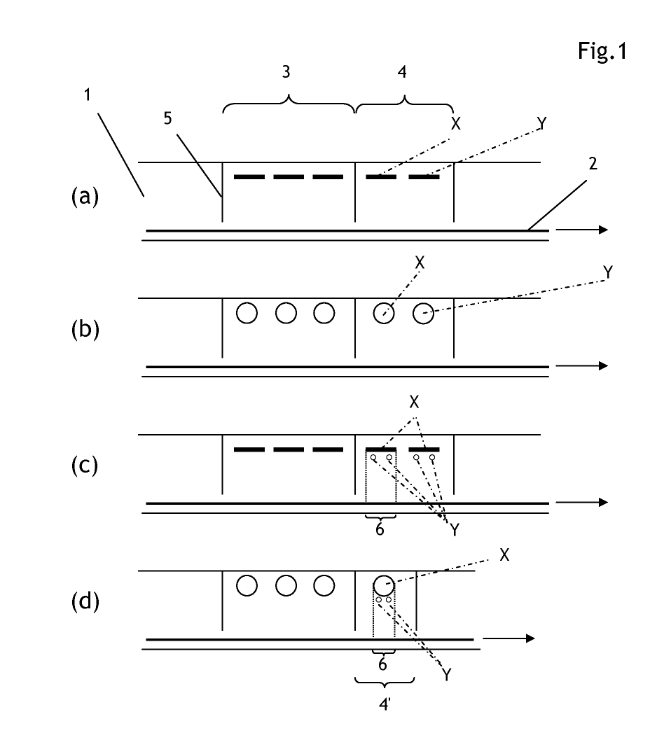

Advantageously, the secondary cathode may be arranged within a magnetic field derived from a main cathode magnetic source, i.e. the device is configured so that the magnetic field associated with the main cathode also acts to enhance sputtering from the secondary cathode and the main cathode magnetic source is adapted to magnetically enhance sputtering from both the main cathode and the secondary cathode. Preferably the main cathode magnetic source provides the only magnetic field adapted to enhance sputtering from the secondary cathode. The secondary cathode may advantageously be arranged within the footprint of the main cathode (the footprint of the main cathode means herein the zone between the cathode itself and the substrate not exceeding the broadness of the cathode; it is schematised in FIGS. 1(c) and 1(d) under number 6). This may assist in providing a more uniform sputtering and/or a more homogeneous coating. When the main cathode is planar, the secondary cathode is preferably arranged in front of at least a portion of the erosion zone of the main cathode. This may also assist in providing a homogeneous coating.

The cathodes may be spaced from each other by a few millimetres; preferably the distance between the main and secondary cathodes is greater than or equal to 1 mm, 2 mm or 3 mm and less than or equal to 40 mm, 30 mm or 20 mm. The distance between both cathodes may depend on the main cathode magnetic field mapping and the secondary cathode may be positioned within the limits of the magnetic field of the main cathode. The secondary cathode may be arranged at a distance from the main cathode such that the magnetic field of the main cathode is large enough to enhance sputtering of the secondary cathode. Preferably, the secondary cathode is arranged within the magnetic field of the main cathode, at a position where said magnetic field has a value of at least 50 Gauss, preferably at least 100 Gauss, more preferably between 100 and 200 Gauss. The secondary cathode sputtering rate may be advantageously controlled by adjusting the distance between the main and secondary cathodes; it may be possible, for example, to decrease, at a given voltage value, the proportion of the second material in the sputtered layer by increasing the distance between the cathodes.

Advantageously, the secondary cathode is adapted to be polarised independently from the main cathode, i.e. a different voltage may be applied to the secondary cathode compared to the main cathode. This may help ensure that the co-sputtering takes place in a controlled way. The quantity of the second material in the sputtered layer may be controlled, inter alia, by adjusting the power applied to the secondary cathode, thereby controlling the speed of sputtering.

By arranging the secondary cathode within the magnetic field of the main cathode, it may be possible to deposit the second material without applying any voltage to the secondary cathode or whilst applying a smaller voltage than the voltage that would have been necessary for depositing the same quantity of material if the secondary cathode had not been arranged in the magnetic field of the main cathode.

Preferably, the secondary cathode comprises a supporting tube adapted to be cooled, which is coated with the material to be sputtered.

This tube may have various shapes: a U shape, a rectangular shape, a rake or comb shape, or it may consist essentially of two distinct, preferably substantially parallel, tubes. It may be preferable to adjust the shape of the secondary cathode according to the desired magnetic field; this may influence the homogeneity of the coating to be deposited.

The tube is advantageously metallic; it may comprise or preferably consist essentially of, a metal or a metal alloy, for example Cu or brass (brass may provide a more rigid tube). It may be cooled, for example by circulation of water inside the tube. Alternatively, the cooling liquid may be a dielectric insulator. This may allow to deposit very little quantities of second material or to avoid deposition of second material, without secondary cathode polarisation. Tubes of more than 2 mm exterior diameter may be used. Preferably, the maximum exterior diameter dimension of the tube or the sum of the maximum exterior diameter dimensions of the distinct tubes does not exceed half of the width of the main cathode, more preferably it does not exceed 20% or 10% of the width of the main cathode. Such sizes may help ensure that cooling is efficient and/or that the secondary cathode does not mask the main cathode by being too large.

The exterior coating of the secondary cathode comprises or preferably, consists essentially of the material to be sputtered, i.e. the target material. This coating may be made by any known method for preparing magnetron sputtering cathode target. The coating may be, for example, a sheet wound around the tube, a wire coiled around the tube, preferably forming a substantially continuous surface coating, or a layer deposited by thermal or plasma projection.

Preferably, the materials of the main and secondary cathodes are different; they may comprise different elements.

The secondary cathode may be used to deposit, for example, Cu, stainless steel, precious metals including Au, Ag, Ru, Rh, Re, Pd, Ir, Pt. It may be used to deposit metals, oxides, nitrides, carbides or ceramic. The secondary cathode may be used to deposit an alloy.

Magnetron co-sputtering devices according to the invention may be used, for example, to deposit materials comprising silver as the minor metal constituent (derived from the secondary cathode), oxygen, and one or more of zirconium, silicon and titanium, for example ZrOₓ—Ag, SiOₓ—Ag, or TiOₓ—Ag; such materials may have a quantity of Ag from a few tenths to a few %. The invention may be used for the deposition of alloys or compounds, especially when precious metals and/or mixtures or alloys of precious metals are to be deposited, e.g. Ag/Pd or Ag/Pt (in this case, silver is the major metal constituent, preferably derived from the main cathode); for the deposition of composite films based on Zn or Mg as major metal constituent, as anticorrosive or auto-cicatrising layers; or, for the deposition of anti-solar coatings on glass. Magnetron co-sputtering devices according to the invention may be used with a same material in both cathodes but in a different proportion, for example one cathode of a Zn—Sn alloy in a proportion 50 to 50, and the other with a Zn—Sn alloy 90:10. Preferably, the material derived from the main cathode is the major constituent of the deposit and the material derived from the secondary cathode is the minor constituent (the minor constituent is present in the deposit in a smaller proportion than the major constituent, e.g. a dopant).

According to further aspects, the present invention provides a magnetron sputtering line according to claim 14 and a product according to claim 15.

By using devices according to the invention, layers comprising, on a metallic species atomic ratio basis, between 0.01 and 40%, preferably between 0.1 and 20%, more preferably between 0.1 and 10% of the second material may be obtained. This ratio is calculated as follows:

$$\frac{atomic \% of the metal of the secondary material ( s )}{\begin{matrix}atomic \% of the metal of the first material + \\ atomic \% of the metal of the secondary material ( s )\end{matrix}}$$

on the basis of, for example, XPS analysis results.

Anti-solar or low-emissive coatings on glass deposited by magnetron co-sputtering devices according to the invention may be of the type:

Glass/dielectric layer/metal/dielectric layer, or
Glass/dielectric layer/metal/dielectric layer/metal/dielectric layer
In these types of layers, the proportion of the second material (e.g. Pd) to the main material (e.g. Ag) in the metallic infrared reflecting layer may be between 1 and 10% by weight.

Antibacterial layers may also be deposited by magnetron co-sputtering devices according to the invention. In this type of layers, the proportion of the second material (e.g. Ag) to the main material (e.g. Ti) may be between 0.2 and 3% by weight (Ag weight/total weight of coating layer).

Co-sputtering of more than two materials may be possible. For example, one material derived from the main cathode, a second material derived from one tube of a secondary cathode and a third material derived from a second tube of a secondary cathode. In that case, the power supply could be identical or different for both tubes.

Substrates that may be coated by magnetron co-sputtering devices according to the invention are for example: glass, metals (e.g. Cu), steel and coated or painted steel, plastics, PET, packaging films.

Embodiments of the invention will now be further described, by way of example only, with reference to FIGS. 1 to 3 and to examples 1 to 3.

FIG. 1 (a) to (d) are schematic views of part of a magnetron sputtering line showing in details two coat zones, of which one is dedicated to co-sputtering; previous known co-sputtering systems (a, b) and co-sputtering systems according to the present invention (c, d) are shown.

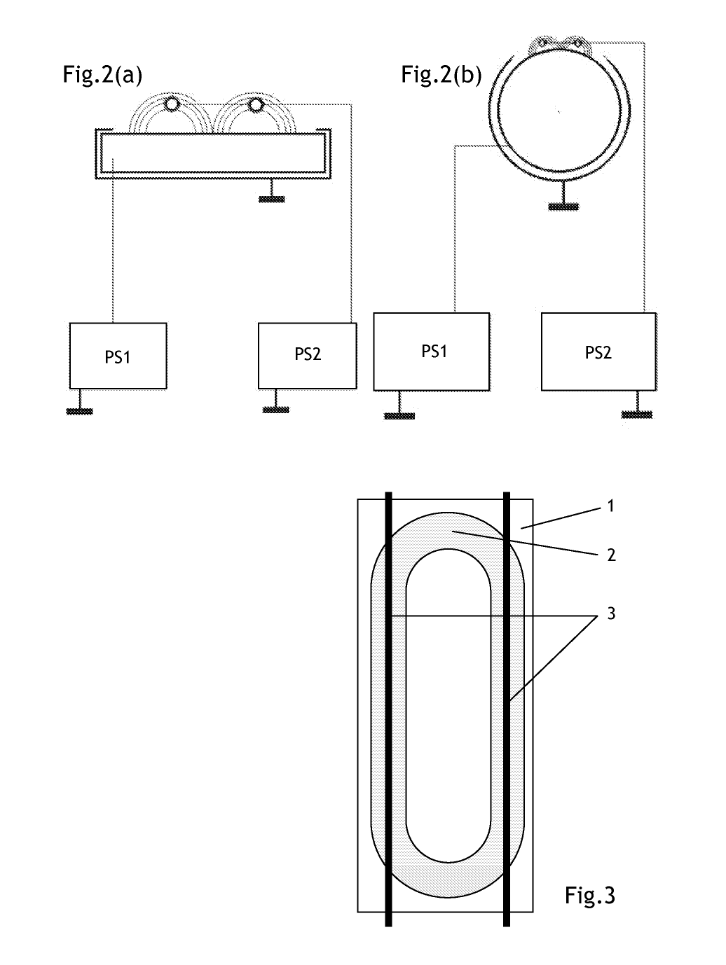

FIG. 2 (a) and (b) are electrical diagrams showing polarisation of main and secondary cathodes;

FIG. 3 is an elevated front schematic view of both main and secondary cathodes;

FIG. 1 shows a portion of a magnetron sputtering line 1 used to sputter deposit a stack of layers on a moving substrate 2 arranged at a substrate position under a vacuum. Two coat zones (3, 4 or 4′) are detailed. Separations 5 are present to delimit coat zones with different atmosphere. Coat zone 3 includes three cathodes of the same material. In embodiments (a) and (c), these are planar cathodes, in embodiments (b) and (d), they are rotating cylindrical cathodes. In coat zone 4 (or 4′), co-sputtering of material X and material Y takes place. Embodiments (a) and (b) show previous known co-sputtering device, with two juxtapositioned cathodes, either planar (a) or rotating cylindrical (b). Embodiments (c) and (d) show co-sputtering devices according to the present invention. In embodiment (c), two cathodes positions are fitted with co-sputtering devices according to the invention. This may allow to form a thicker layer on the substrate. In embodiment (d), one cathode positions is fitted with a device according to the invention. This may allow to have a shorter magnetron sputtering line. In co-sputtering devices according to embodiments (c) or (d), the secondary cathode (Y) is made of two distinct parallel tubes positioned between the main cathode and the substrate, in the footprint 6 of the main cathode (X) and in its magnetic field.

FIG. 2 shows independently controllable electrical polarisation of main and secondary cathodes in case of planar main cathode (figure a) and rotating cylindrical main cathode (figure b). PS1 is the power supply for the main cathode, PS2 for the secondary cathode. In this figure, the substrate to be coated (not visible) is in the upper part of the drawing (whereas FIG. 1 shows sputter-down systems). The secondary cathode is made of two distinct parallel tubes.

FIG. 3 shows a main planar cathode 1, with erosion zone 2, and a secondary cathode 3 made of two distinct parallel tubes positioned in front of the erosion zone.

### EXAMPLE 1

### ZrOₓ—Ag Coating on Glass

A magnetron co-sputtering device is made of a main planar rectangular cathode of zirconium (dimensions: 450×150×8 mm) and of a secondary cathode according to the invention consisting of two distinct parallel tubes made of brass, having an exterior diameter of 3 mm. A wire of silver with a square section of 1 mm, is coiled around the tubes to form a substantially continuous coating. The tubes are positioned between the main cathode and the substrate to be coated, in a plane which is parallel to the main cathode, at a distance of around 4 mm from the main cathode. Sputtering takes place in an oxidising atmosphere containing Ar (flow rate: 112 sccm) and O₂ (flow rate: 30 sccm), with a total pressure of 7×10⁻³ mbar. The power applied to the main cathode is 2 kW in a bipolar pulsed mode with a frequency of 250 kHz and a positive pulse of 1056 ns. Power applied to the secondary cathode is made to vary between 0 and 50 W (see Table I) in a single-pole pulsed mode with a frequency of 150 kHz and a positive pulse of 2496 ns. The distance between the main cathode and the substrate is 9.5 cm and the substrate carrier moves in front of the cathodes to ensure a homogeneous deposition. The substrate is connected to earth.

A layer of ZrOₓ incorporating Ag is formed on the substrate, in this case a sheet of flat, soda-lime float glass substrate.

Atomic % of elements present in the surface of the coating layer are given in Table I. They were measured using the XPS conditions described herein. Peaks used for the determination of these elements are given in Table I. Ratios of Ag/(Ag+Zr), expressed in % are also given in Table I.

TABLE I

| | power applied to | atomic % (measured by XPS) | | | | |
|---|---|---|---|---|---|---|
| | secondary cathode | Ag | Zr | O | C | % Ag/ |
| example | [W] | 3d5/2 | 3d | 1s | 1s | (Ag + Zr) |
| 1a | 0 | 0.1 | 29.5 | 50.0 | 20.4 | 0.3 |
| 1b | 25 | 0.9 | 27.8 | 48.1 | 23.2 | 3.1 |
| 1c | 50 | 1.4 | 29.0 | 47.4 | 22.2 | 4.6 |

### EXAMPLE 2

### SiOₓ—Ag Coating on Stainless Steel

Example 2 is made as in example 1 except that:

the main cathode is made of silicium, and

the substrate is a sheet of stainless steel

the substrate carrier is linked to the power supply which is set at 0 V; an auto-polarisation of about 30 V is however detected by the measurement apparatus linked to the power supply.

A layer of SiOₓ incorporating Ag is formed on the substrate, in this case a stainless steel substrate.

Atomic % of elements present in the surface of the coating layer and ratios of Ag/(Ag+Si) are given in Table II.

TABLE II

| | power | | | | | | | |
|---|---|---|---|---|---|---|---|---|
| | applied to | atomic % (measured by XPS) | | | | | | |
| | secondary | Ag | Si | O | C | Ar | F | % |
| example | cathode [W] | 3d5/2 | 2p | 1s | 1s | 2p | 1s | Ag/(Ag + Si) |
| 2a | 0 | 0.0 | 35.4 | 58.3 | 6.0 | 0.2 | 0.2 | 0.0 |
| 2b | 25 | 0.1 | 36.1 | 59.8 | 3.7 | 0.0 | 0.3 | 0.3 |
| 2c | 50 | 1.7 | 34.4 | 56.5 | 7.0 | 0.0 | 0.4 | 4.6 |

### EXAMPLE 3

### TiOₓ—Ag Coating on Stainless Steel

Example 3 is made as in example 2 except that:

the main cathode is made of titanium, and

the substrate carrier is linked to the power supply which is set at 0 V; an auto-polarisation of about 20 to 30 V is however detected by the measurement apparatus linked to the power supply.

Atomic % of elements present in the surface of the coating layer after removal of the outer surface layer and ratios of Ag/(Ag+Ti) are given in Table III.

Removal of the outer surface layer before XPS analyses consisted in an in-situ bombardment by a beam of argon ions of 3 keV with a current of 1 μA during 90 seconds. The thickness of material removed accordingly was about 40 Å at maximum.

TABLE III

| | power | | | | | | |
|---|---|---|---|---|---|---|---|
| | applied to | atomic % (measured by XPS) | | | | | |
| | secondary | Ag | Ti | O | C | Ar | % |
| example | cathode [W] | 3d5/2 | 2p | 1s | 1s | 2p | Ag/(Ag + Ti) |
| 3a | 25 | 9.0 | 28.5 | 59.5 | | 3.0 | 24.0 |
| 3b | 50 | 19.1 | 24.3 | 52.5 | 1.9 | 2.2 | 43.9 |

XPS Analysis Conditions:

XPS analysis was carried on a VG ESCALAB 220iXL spectrometer. Pressure in the analysis chamber was around 1.10⁻⁹ Torr. X-rays source was monochromatic and line KαAl (E=1486.6 eV) was used. Power applied to the X-rays source was 240 W. The analysed surface was 1 mm². As the analysed samples were insulant, an electron gun with an energy of 6 eV was used to compensate the charge-effect of the sample produced during the X-irradiation.

General XPS spectra, recorded in a bandwidth of 50 eV, provided a qualitative analysis. The semi-quantitative analysis was made by recording at high resolution main photoelectrons peaks characterizing elements present in the sample. These were recorded in a bandwidth of 20 eV.

Quantification was made on the basis of the photoelectrons peaks areas (I_{A} for a given A element) after removal of the continuous background which is approximated by a base line of the Shirley type according to the formula:

I_{A}=N_{A}*σ_{A}(hν)*λ_{M}(E_{A})*G(E_{A})

In the quantification software used, function λ_{M}(E_{A}) is approximated by λ_{M}(E_{A})=E_{A}^{0.6}
I_{A}=N_{A}*σ_{A}(hν)*E_{A}^{0.6}*G(E_{A}), wherein:
I_{A}: typical photoelectrons peak area of element A
N_{A}: number of A atoms in the analysed volume
σ_{A}(hν): ionisation effective cross-section of the ionised level producing the photoelectrons peak which is typical of element A
λ_{M}(E_{A}): inelastic photoelectron mean free path which is typical of element A at the kinetic energy E_{A}
G(E_{A}): transmission factor of the used electrons spectrometer, which is a function of the kinetic energy of the photoelectron.

1. Magnetron co-sputtering device comprising a main magnetron cathode and a secondary cathode adapted to be associated with each other to sputter deposit a material on a substrate arranged at a substrate position, the material comprising a first material derived from the main cathode and a second material derived from the secondary cathode, wherein the secondary cathode is arranged between the main cathode and the substrate position, at a position selected from:
(i) a position within a magnetic field derived from a main cathode magnetic source, and
(ii) a position within the footprint of the main cathode.

2. Magnetron co-sputtering device according to claim 1, wherein the secondary cathode is arranged at a position within the magnetic field derived from the main cathode magnetic source, which is within the footprint of the main cathode.

3. Magnetron co-sputtering device according to claim 1, wherein the secondary cathode is arranged in front of the erosion zone of the main cathode.

4. Magnetron co-sputtering device according to claim 1, wherein the secondary cathode is arranged at a distance from the main cathode ranging from 1 mm to 40 mm.

5. Magnetron co-sputtering device according to claim 1, wherein the secondary cathode is arranged within the magnetic field derived from the main cathode magnetic source, at a position where said magnetic field has a value of at least 50 Gauss.

6. Magnetron co-sputtering device according to claim 1, wherein the main cathode magnetic source provides the only magnetic field adapted to enhance sputtering from the secondary cathode.

7. Magnetron co-sputtering device according to claim 1, wherein the secondary cathode is adapted to be polarised independently from the main cathode.

8. Magnetron co-sputtering device according to claim 1, wherein the secondary cathode comprises a metallic tube adapted to be cooled, having a material to be sputtered at its external surface.

9. Magnetron co-sputtering device according to claim 8, wherein the secondary cathode consists essentially of two distinct tubes.

10. Magnetron co-sputtering device according to claim 8, wherein the metallic tube of the secondary cathode is adapted to be cooled by the circulation of a cooling liquid selected from the group consisting of water and dielectric insulators.

11. Magnetron co-sputtering device according to claim 8, wherein the secondary cathode comprises a supporting tube coated with a material to be sputtered.

12. Magnetron co-sputtering device according to claim 11, wherein the supporting tube of the secondary cathode comprises Cu or brass.

13. Magnetron co-sputtering device according to claim 11, wherein the coating comprising the material to be sputtered consists essentially of one of the group consisting of a sheet wound round the tube, a wire coiled round the tube, and a thermally or by plasma projected layer.

14. Magnetron sputtering line comprising at least one magnetron co-sputtering device according to claim 1.

15. Coated product manufactured using a magnetron co-sputtering device according to any of claim 1.

16. Coated product according to claim 15, wherein the layer comprising the first and second materials comprises between 0.1 and 40% of the second material, on a metallic species atomic ratio basis.
